(19) United States
(12) Patent Application Publication
(10) Pub. No.: US 2025/0036144 A1
(43) Pub. Date: Jan. 30, 2025

(54) UNDERWATER VEHICLES FOR VESSEL CHARACTERIZATION

(71) Applicant: CELLULA ROBOTICS, LTD., Burnaby (CA)

(72) Inventors: James Eric JACKSON, Burnaby (CA); Jacqueline NICHOLS, Burnaby (CA); Adrian WOODROFFE, Burnaby (CA)

(21) Appl. No.: 18/854,892

(22) PCT Filed: Apr. 5, 2023
(86) PCT No.: PCT/IB2023/000202

§ 371 Date: Oct. 7, 2024

Related U.S. Application Data
(60) Provisional application No. 63/327,493, filed on Apr. 5, 2022.

(51) Int. Cl. G05D 1/689; B63G 8/00; G01R 33/02; G01S 7/539; G05D 105/80

(52) U.S. Cl. CPC G05D 1/689; B63G 8/001; G01R 33/02; G01S 7/539; B63G 2008/004; G05D 2105/89

(57) ABSTRACT

An autonomous underwater vehicle (AUV) comprising one or more propulsion devices that propel the AUV, one or more sensors that generate sensor data indicative of a signature of a vessel, memory, and processing circuitry. The processing circuitry determines an underwater position at which the AUV collects the sensor data, controls the one or more propulsion devices to move the AUV to the underwater position, receives the sensor data from the one or more sensors while the AUV is at the underwater position, and stores the sensor data in the memory.

### CROSS REFERENCE TO RELATED APPLICATIONS

This application claims priority to U.S. Provisional Application 63/327,493, filed on Apr. 5, 2022, the entire contents of which are incorporated herein by reference.

### FIELD

Example embodiments relate to underwater vehicles for vessel characterization, for example, to autonomous underwater vehicles (AUVs) that collect data indicative of magnetic, acoustic, electronic, pressure, and seismic signatures of a vessel.

### BACKGROUND

Underwater radiated noise and other characteristics of a marine vessel can be detected from long ranges by acoustic sensors and sonar. Various signatures of vessels, such as acoustic, magnetic, and electronic signatures, can be used by sea mines for target detection. Accurate characterization of these signatures before a vessel enters the field may be useful for protecting the vessel from submarines and mines. A vessel's emissions may also have impacts marine life and/or civilian marine operations, and in this case, vessel characterization may be useful for reducing or avoiding those impacts. Vessel characterization may be carried out on a regular basis, for example, after planned or unplanned vessel maintenance.

### BRIEF DESCRIPTION OF THE DRAWINGS

The present disclosure is described in conjunction with the appended figures, which are not necessarily drawn to scale:

FIG. 1 illustrates a system according to at least one example embodiment.

FIG. 2 is a schematic sectional view of a deployment including elements from the system of FIG. 1.

FIGS. 3 and 4 illustrate respective example implementations for obtaining vessel characterization measurements from a schematic top view.

FIG. 5 illustrates a method for performing vessel characterization according to at least one example embodiment.

FIG. 6 illustrates a method for performing vessel characterization according to at least one example embodiment.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

It will be appreciated from the following description, and for reasons of computational efficiency, that the components of the system can be arranged at any appropriate location within a distributed network of components without impacting the operation of the system.

Furthermore, it should be appreciated that the various links connecting the elements can be wired, traces, optical, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a PCB, or the like.

Various aspects of the present disclosure will be described herein with reference to drawings that may be schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

Related art methods for characterizing a marine vessel include using fixed underwater ranges that include appropriate sensors for detecting various signatures of a vessel. These fixed ranges introduce an operational constraint where the vessel must travel to the range. For example, in Canada, there are two ranges, one on the East Coast and one on the West Coast. The related art also includes temporarily deployed arrays of sensors for magnetic measurements. However, these arrays require shallow water for deployment, and shallow water has an impact on the vessel's signature(s) and presents an operational risk with increased exposure to seafloor mines and potential shore-based attack.

Inventive concepts propose systems, devices, and methods to overcome limitations and solve various problems associated with related art methods and devices for vessel characterization. In some examples, one or more AUVs are used to collect data for characterizing a vessel. The AUV(s) may be equipped with an onboard navigation solution to enable accurate data collection. The proposed AUV(s) may be equipped with one or more of the following sensors for characterization, communication, and positioning: sensor(s) for obtaining magnetic signature of the vessel of interest; sensor(s) for obtaining acoustic signature of the vessel of interest; sensor(s) for obtaining electric signature of the vessel of interest; a transceiver to allow communication with the vessel while the AUV is at the surface; a transceiver to allow communication with other AUVs while deployed; an acoustic beacon to enable accurate positioning relative to the surface vessel; an acoustic beacon to allow acoustic positioning with other AUVs; and a Global Navigation Satellite System (GNSS) receiver (e.g., Global Positioning System (GPS)) for establishing AUV position while the AUV is at the surface. In some examples, multiple sensors are used to assist with establishing positions of the AUV(s) relative to the vessel and/or to other AUVs. For example, the GNSS system of each AUV may be combined with one or more other positioning systems on the AUV to gather accurate position information for the AUV. Such other positioning systems include one or more of a high precision Inertial Navigation System (INS), a Doppler Velocity Log (DVL), and an acoustic positioning or correction system such as an ultrashort baseline (USBL) acoustic system or a long baseline (LBL) acoustic system. In addition, each AUV may also have accurate knowledge of the vessel's position from a GPS/GNSS device on the vessel. Thus, each AUV may have accurate position knowledge of the vessel and/or of the other AUVs so that each AUV can position itself in a location that is useful (e.g., optimized) for vessel acoustic and/or magnetic characterization.

Although example embodiments are discussed with reference to obtaining a vessel's signature(s), inventive concepts herein may have other applications, such as vessel hull corrosion inspections.

One example procedure for surveying a vessel's signature(s) may include: the AUV(s) are deployed from the vessel of interest; the AUV(s) establish their GNSS positions with their GNSS receivers; the AUV(s) descend from the surface of the water after establishing GNSS position; the AUV(s) automatically position themselves underwater for the upcoming set of maneuvers by the vessel of interest and perform a calibration check to ensure proper positioning; and the AUV(s) hover in place underwater while recording sensor data as the vessel of interest performs the set of maneuvers. Additionally or alternatively, the vessel of interest stays stationary and the AUV(s) complete their maneuvers. Thereafter, the recorded sensor data is transmitted from AUV(s) by radio (e.g., Wi-Fi) or downloaded upon AUV recovery to recovered to the deck of the vessel.

In some examples where a “swarm” of AUVs are deployed, multiple signatures of the vessel may be acquired in a single series of vessel or AUV maneuvers. Here, one of the AUVs may be designated as a main or primary AUV and act as a central controller for the other AUVs. The main AUV may provide positioning updates to the other AUVs and communicate with the vessel while other AUVs are submerged to provide the positioning updates and/or provide other updates on planned vessel maneuvers. The main AUV may comprise higher quality positioning and communication components compared to the other AUVs.

As may be appreciated, inventive concepts provide for efficient and effective vessel characterization at any marine location including deep water locations, and thus, avoids problems related to shallow water characterization and the need to travel to a specialized location which saves time and cost.

Inventive concepts will now be further described with reference to the figures.

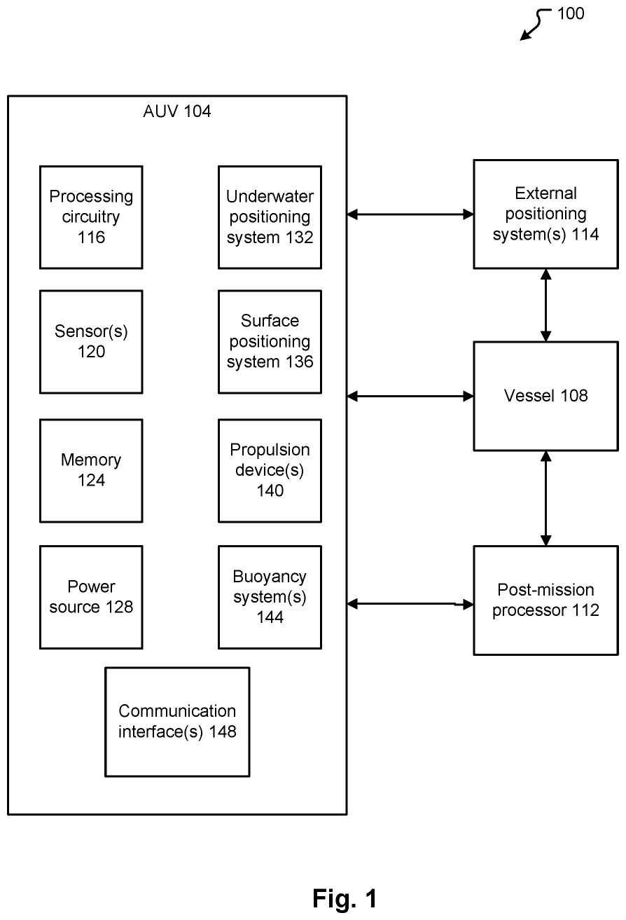

FIG. 1 illustrates a block diagram of a system 100 according to at least one example embodiment. The system 100 includes an AUV 104, a vessel 108, a post-mission processor 112, and external positioning system(s) 114. As indicated by the two-way arrows, these elements of the system 100 may be in wired and/or wireless communication with one another, although not necessarily at all times during the methods described herein. Stated another way, an element may lose the ability to communicate (or have the ability to communicate limited) with another element at certain points during a vessel characterization process. For example, when an AUV 104 is at or above the surface of the water, the AUV 104 is able to communicate with an external positioning system 114 (e.g., embodied as a GPS satellite) but loses the ability to communicate with the system 114 when the AUV 104 is submerged below the water's surface.

In general, the AUV 104 includes processing circuitry 116, sensor(s) 120, memory 124, power source 128, underwater positioning system(s) 132, surface positioning system(s) 136, propulsion device(s) 140, buoyancy system(s) 144, and communication interface(s) 148, all of which in more detail below with reference to FIG. 1 and the remaining figures. In at least one example embodiment, the AUV 104 is actually a remotely operated vehicle (ROV) that is controllable (wired or wirelessly) remotely by an operator instead of or in addition to being autonomously controlled.

The vessel 108 may correspond to a surface vessel, such as a naval ship, commercial liner, or other marine vessel suited for above surface marine travel. In some examples, the vessel 108 corresponds to a subsurface marine vessel, such as a submarine or other vessel suitable for subsea travel. In any event, at least one example embodiment relates to characterizing the vessel 108, which may include sensing magnetic, acoustic, electronic, pressure, and/or seismic emissions from the vessel 108 to determine corresponding magnetic, acoustic, electronic, pressure, and/or seismic signatures for the vessel 108. One or more of these signatures may prove useful for naval applications, such as sea mine and sonar avoidance, or for civilian applications, such as noise reduction for environmental reasons (e.g., marine life preservation) and/or interference reduction to subsea components (e.g., during subsea drilling, pipe inspection, etc.). The vessel 108 may comprise the same or similar components as those illustrated for the AUV 104 and discussed in more detail below.

The post-mission processor 112 may comprise suitable hardware and/or software for processing sensor data from an AUV 104 for the sake of vessel characterization, which may include determining the above mentioned signatures of the vessel 108. The post-mission processor 112 may comprise processing circuitry having the same or similar structure as the processing circuitry 116 of the AUV 104 discussed below. In some examples, the post-mission processor 112 comprises a graphical user interface (GUI), such as a display, that enables user interaction to sift through sensor data and display of outputs relevant to the vessel characterization. One non-limiting example of the post-mission processor is a personal computer, such as a laptop, executing one or more software applications for vessel characterization.

The external positioning system(s) 114 may comprise a satellite-based system, such as an GNSS, or other suitable system for determining positions of the AUV 104 and/or the vessel 108. As such, the external positioning system(s) 114 may be remotely located from the AUV 104 and the vessel 108.

Various components of the AUV 104 will now be discussed, beginning with the processing circuitry 116 and memory 124. The processing circuitry 116 includes suitable components for carrying out AUV component control, AUV navigation, and the various other computer-related or computer-controlled tasks described herein. Such processing circuitry 116 may comprise software, hardware, or a combination thereof. The processing circuitry 116 may be coupled to memory 124 that includes executable instructions. In this case, the processing circuitry 116 may comprise a processor (e.g., a microprocessor) that executes the instructions on the memory 124. The memory 124 may correspond to any suitable type of memory device or collection of memory devices configured to store instructions and/or other data (e.g., sensor data). Non-limiting examples of suitable memory devices that may be used include flash memory, Random Access Memory (RAM), Read Only Memory (ROM), variants thereof, combinations thereof, or the like. In some embodiments, the memory 124 and the processor may be integrated into a common device (e.g., a microprocessor may include integrated memory 124). Additionally or alternatively, the processing circuitry 116 may comprise hardware, such as an application specific integrated circuit (ASIC). Other non-limiting examples of the processing circuitry 116 include an Integrated Circuit (IC) chip, a Central Processing Unit (CPU), a Graphics Processing Unit (GPU), a microprocessor, a Field Programmable Gate Array (FPGA), a collection of logic gates or transistors, resistors, capacitors, inductors, diodes, or the like. Some or all of the processing circuitry 116 may be provided on a Printed Circuit Board (PCB) or collection of PCBs. It should be appreciated that any appropriate type of electrical component or collection of electrical components may be suitable for inclusion in the processing circuitry 116.

The sensor(s) 120 may comprise one or more sensors suitable for sensing parameters that are relevant to vessel characterization. For example, the sensors 120 may include sensors for sensing magnetic emissions of the vessel 108 (e.g., one or more magnetometers), sensors for sensing acoustic emissions of the vessel 108 (e.g., a sonar sensor system, such as a single-beam sonar system, side-scan sonar system, or multibeam sonar system), sensors for sensing electronic emissions of the vessel 108 (e.g., one or more electric field sensors, such as a current sensor or sensor suitable for sensing underwater electric potential (UEP) and/or extremely low frequency electric (ELFE) fields), sensors for sensing seismic emissions of the vessel 108 (e.g., a seismic sensor), and/or sensors for sensing pressure emissions of the vessel 108 (e.g., a pressure transducer). Stated another way, the sensors 120 have suitable hardware and/or software for generating sensor data that is used to determine one or more signatures of the vessel 108 described herein. The sensors 120 may also include sensors not necessarily associated with characterization of the vessel 108, but that are useful for other purposes, such as for general operation the AUV 104 in an underwater environment. For example, the sensors 120 may comprise an accelerometer for determining AUV 104 orientation, a temperature sensor, a water quality sensor, a light sensor, a power sensor, and/or the like.

The power source 128 may comprise hardware and/or software for powering the other illustrated and non-illustrated components of the AUV 104. In at least one example, the power source 128 comprises a battery, such as a rechargeable battery. However, example embodiments are not limited thereto and the power source 128 may comprise a fuel cell (e.g., a hydrogen fuel cell) or other fueled power source.

The underwater positioning system 132 may comprise suitable hardware and/or software for determining an underwater position of the AUV 104, for example, relative to the vessel 108 and/or relative to other AUVs 104. Nonlimiting examples of the underwater positioning system 132 include a high precision Inertial Navigation System (INS), a Doppler Velocity Log (DVL), and/or an acoustic system such as an ultrashort baseline (USBL) acoustic system or a long baseline (LBL) acoustic system.

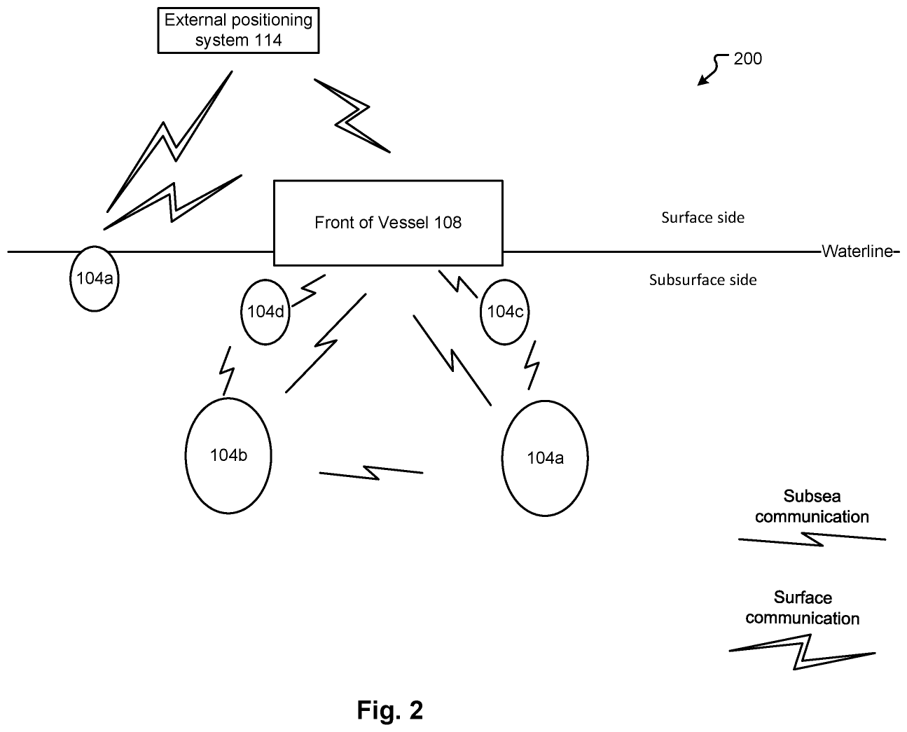

The surface positioning system(s) 136 may comprise suitable hardware and/or software for determining and/or tracking a surface position of the AUV 104 (e.g., a position of the AUV 104 when the AUV 104 is at or above the water's surface). Non-limiting examples of a surface positioning system 136 include a GNSS or other satellite-based system that provides positioning, navigation, and/or timing services for the AUV 104. In at least one embodiment, the surface positioning system 136 determines a surface position of the AUV 104 relative to a position of the vessel 108 and/or relative to a position of another AUV 104 (or relative to multiple AUVs 104). As described in more detail below with reference to FIG. 2 and beyond, the surface positioning system 136 and the underwater positioning system 132 may both be used to determine and help guide the AUV 104 to an appropriate underwater position for taking sensor measurements useful for vessel characterization.

Still with reference FIG. 1, the propulsion device(s) 140 may include suitable hardware and/or software for causing underwater movements of the AUV 104. The propulsion device(s) 140 may include one or more motors (e.g., electric motors) with associated propeller(s) or thruster(s) or jets, as well as fixed and/or pivoting fins to control pitch, roll, and yaw of the AUV 104.

The buoyancy system(s) 144 may comprise suitable components for controlling the buoyancy of the AUV 104. For example, the AUV 104 may include a variable buoyancy system (VBS) that helps control AUV depth.

Communication interface(s) 148 may include suitable hardware and/or software for enabling wired and/or wireless communication between components of the AUV 104 and between the AUV 104 and the vessel 108, post-mission processor 112, and/or the external positioning system(s) 114. For example, the communication interface(s) 148 may include interfaces for serial communication (e.g., a peripheral component interconnect express (PCIe) bus), acoustic communication, blue light communication, Ethernet communication, Wi-Fi communication, cellular communication, BLUETOOTH communication, satellite communication, universal serial bus (USB) communication, and/or the like.

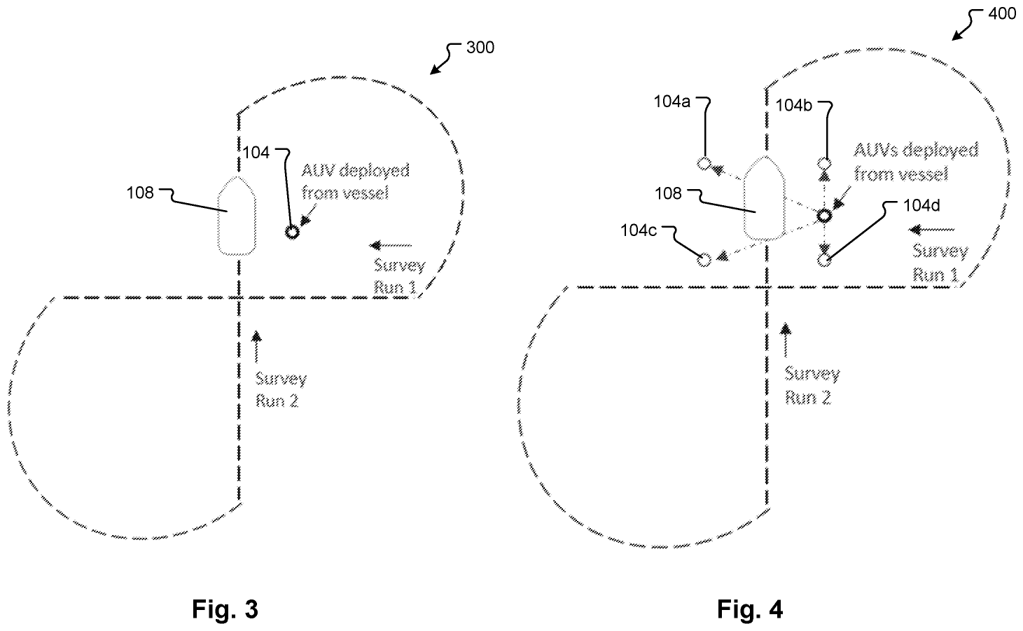

FIG. 2 is a schematic sectional view of a deployment 200 including elements from the system 100 of FIG. 1. As may be appreciated, FIG. 2 illustrates various possibilities for surface communication and underwater communication. FIGS. 3 and 4 illustrate respective example implementations 300 and 400 for obtaining vessel characterization measurements from a schematic top view. Implementation 300 illustrates using a single AUV 104 for vessel characterization while the vessel 108 performs a series of maneuvers (as survey runs 1 and 2) around the AUV 104 with the AUV 104 maintains its underwater position. Although not explicitly illustrated, the AUV 104 in FIG. 3 may move from an initial deployment position on the water's surface to an underwater position for taking vessel characterization measurements (where such movement may occur in accordance with the discussion below).

Meanwhile, the deployment 200 corresponds to the sectional view of the top view shown for the implementation 400. As may be appreciated, each of FIGS. 2 and 4 illustrate four AUVs 104a to 104d, with FIG. 2 illustrating an initial surface position for AUV 104a as well as the AUVs 104a to 104d in respective underwater positions for taking vessel characterization measurements. As shown in FIGS. 3 and 4, the series of maneuvers of the vessel 108 may form a shape that has at least two lines of symmetry. For example, the vessel 108 may travel in a first loop (e.g., upper right loop) and then a second loop (e.g., lower left loop). The first and second loops may have substantially the same shape, which involves two straight paths connected by a curved path. The lengths of each loop may be substantially the same. As may be appreciated, the shape and length of each loop may vary depending on the signature being determined. In addition, other types of maneuvers that result in differently shaped paths may be used.

As shown in FIG. 2, subsea communication may occur between the AUVs 104a to 104d themselves and/or between the vessel 108 and each AUV 104, and surface communication may occur between the AUV 104a and vessel 108, between the AUV 104a and the external positioning system 114 and/or between the vessel 108 and the external positioning system 114. Although not explicitly shown, it should be understood that other AUVs 104b to 104d may also conduct surface communication with the external positioning system and/or the vessel 108. In some examples, however, AUV 104a acts as the main AUV and communicates position information to the other AUVs 104b to 104d using surface communication and/or underwater communication. More or fewer AUVs 104 may be deployed.

In one nonlimiting example, each AUV 104 uses the surface positioning system 136 and the external positioning system 114 upon initial deployment from the vessel 108 to establish a first surface position in the water relative to the vessel 108 (or another AUV 104). The first surface position may correspond to the AUV deployment location shown in FIG. 4. Each AUV 104 may then determine to move to a respective second surface position in the water relative to the vessel 108 (or another AUV 104) before submerging to a respective underwater position. In some examples, the underwater position is defined to be a position that is some depth directly below the second surface position so that the AUV 104 merely submerges to from the second surface position to arrive at the underwater position without significant horizontal movement. In other examples, each AUV 104 submerges at some horizontal distance away from the underwater position and navigates to the underwater position. In any event, FIG. 4 illustrates how each AUV 104 moves from the first surface position (i.e., where the AUVs are deployed) to respective positions around the vessel 108.

In some cases, each AUV 104 uses the underwater positioning system 132 to confirm arrival at the appropriate underwater position or to navigate to the appropriate underwater position. For example, each AUV 104 and the vessel 108 (or another AUV 104) exchange acoustic signals with respective underwater positioning systems to determine whether the AUV 104 has arrived at the intended underwater position for taking vessel characterization measurements with sensor(s) 120. Each AUV 104 then makes underwater positional adjustments to the extent such positional adjustment is needed. Thereafter, each AUV 104 may be controlled to maintain its underwater position as the vessel 108 performs a series of maneuvers (as in FIGS. 3 and 4). In other examples, each AUV 104 (or a single AUV 104 in the implementation 300) may be controlled to move to another underwater position to take additional vessel characterization measurements while the vessel 108 remains stationary or as stationary as possible given sea and weather conditions.

Here, it should be understood that determining a surface position of an AUV 104 may involve determining a surface pose of the AUV 104, where the surface pose refers to both position and orientation of the AUV 104 at the surface of the water. Similarly, determining an underwater position of an AUV 104 may involve determining an underwater pose of the AUV, where the underwater pose refers to both position and orientation of the AUV 104 in the underwater environment. In any event, orientation of the AUV 104 may be determined and tracked relative to an orientation of the vessel 108 in the same or similar manner as positioning of the AUV 104 is determined relative to the vessel 108, such as by exchanging surface and/or underwater signals with the vessel 108 and/or other AUVs 104 to aid with determining and tracking AUV 104 and vessel 108 orientation. Determining an orientation of the AUV 104 may be important for ensuring that the sensor(s) 120 of the AUV 104 are in an acceptable or optimal location relative to the vessel 108 for detecting vessel emissions. For example, detecting one type of vessel emissions (e.g. magnetic emissions) may require a different orientation of the AUV 104 than detecting another type of vessel emissions (e.g., acoustic emissions) to account for the magnetic sensors and acoustic sensors being mounted at different locations on the AUV 104. In some cases, the surface position(s) and underwater position(s) determined for the AUV 104 are agnostic to orientation of the AUV 104 and sensor(s) 120. In this case, orientation of the AUV 104 and/or the vessel 108 are not necessarily determined, and only AUV 104 and/or vessel 108 positioning is determined.

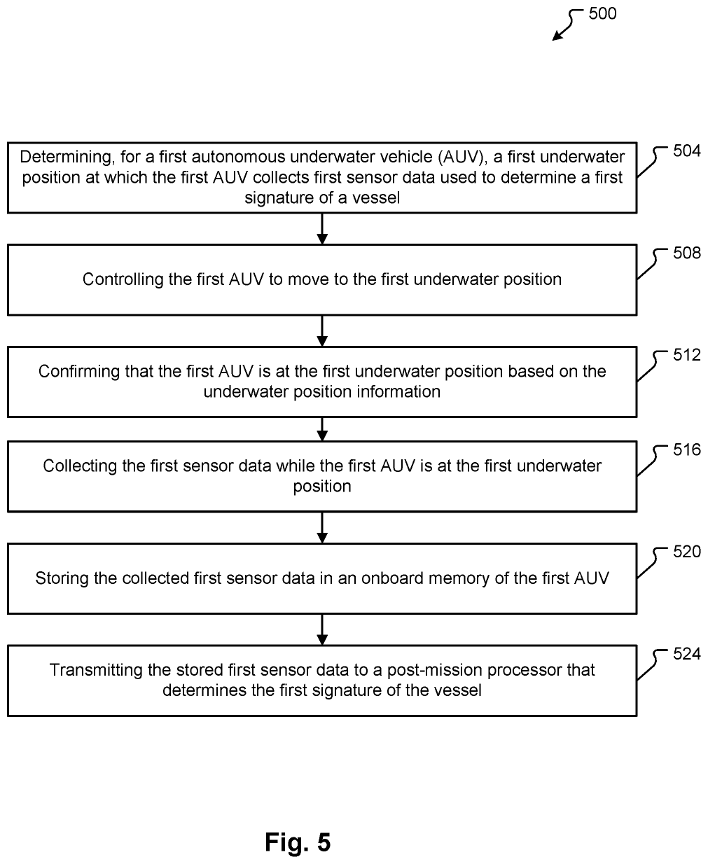

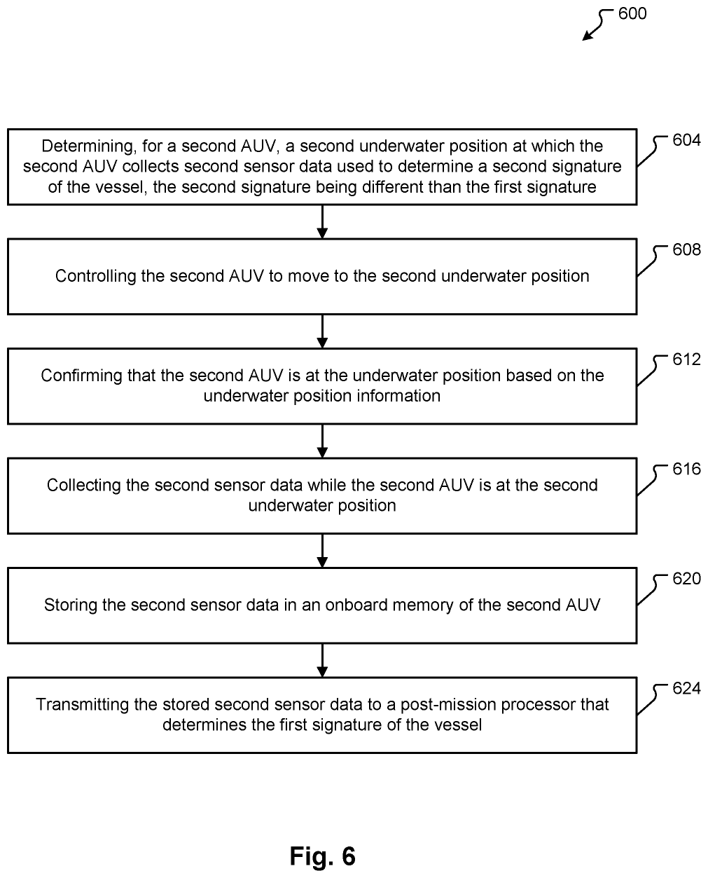

FIG. 5 illustrates a method 500 for performing vessel characterization according to at least one example embodiment. The method 500 may be carried out by various elements described herein, including by the processing circuitry 116 controlling a corresponding AUV 104 to move and to collect sensor data with sensors 120. FIG. 5 will be discussed with reference to a first AUV 104a, but the method 500 may be applied to additional AUVs as described in more detail below with reference to FIG. 6.

Operation 504 includes determining, for a first AUV 104a, a first underwater position at which the first AUV 104a collects first sensor data used to determine a first signature of a vessel. The first underwater position may be determined based on a variety of factors, such as the series of maneuvers to be performed by the vessel 108 (e.g., as in FIGS. 3 and 4), the series of maneuvers to be performed by the AUV 104a, and/or the type of signature being measured (e.g., electric, magnetic, acoustic, etc.). For example, the processing circuitry 116 may receive or determine information that identifies the series of maneuvers of the vessel 108 and/or of the AUV 104a, and then use that information to determine the underwater position for the AUV 104a as a position that is useful or optimal for sensing data that will be used to determine one or more signatures of the vessel 108. The type of signature or signatures being measured may also have an effect on determining underwater positions of the AUV 104a. For example, taking sensor measurements for one type of signature may require the AUV(s) 104 to be closer to the vessel 108, in a different position relative to the vessel 108, and/or at a different depth compared to sensor measurements for other types of signatures.

Operation 508 includes controlling the first AUV 104a to move to the first underwater position. For example, the processing circuitry 116 controls the propulsion device(s) 140 to move the AUV 104a to the underwater position. In one specific implementation, operation 508 includes determining a first surface position of the first AUV 104a relative to the vessel 108, controlling the first AUV 104a to move from the first surface position to a second surface position relative to the vessel 108, and controlling the first AUV 104a to submerge at the second surface position and move to the first underwater position. As may be appreciated, the surface positions are positions of the AUV 104a that are at or above the water's surface. In some examples, the underwater position is directly below second surface position so that the AUV 104a merely submerges itself at the second surface position to arrive at or near the first underwater position. The AUV 104a may move from the first surface position to the second surface position while exposed at the water's surface for the entire path and/or by submerging for at least part of the path. The AUV 104a may determine and continually monitor its surface position using the surface positioning system 136 and the external positioning system 114.

Operation 512 includes confirming that the first AUV 104a is at the first underwater position. For example, the first AUV 104a may confirm that the first underwater position based on underwater position information received and/or generated by the underwater position system 132. The underwater position information for the first AUV 104a may comprise information that identifies a position of the first AUV 104a relative to the vessel 108 and/or relative to one or more other AUVs 104. To the extent that operation 512 reveals the first AUV 104a is not at the first underwater position, operation 512 includes controlling the AUV 104a to adjust its position until at the first underwater position. In one example, the first AUV 104a determines its underwater position by pinging the vessel 108 and determining whether the first AUV 104a is the proper distance and depth away from the vessel 108.

Additionally or alternatively, the first AUV 104a communicates with another AUV 104 which is still at the water's surface and in communication with the external positioning system 114 to assist with verifying the underwater position of the first AUV 104a. Still further, the first AUV 104a may communicate with another AUV 104 that is also submerged to help verify the underwater position of the first AUV 104a. In this case, the another AUV 104 may be communicating the vessel 108 to ensure that the first AUV 104a is at the first underwater position. Here, it should be appreciated that operation 512 may be omitted if desired and/or performed repeatedly throughout the method 500 so as to ensure the first AUV 104a maintains proper underwater positioning.

Operation 516 includes collecting the first sensor data while the first AUV 104a is at the first underwater position. For example, the sensors 120 generate the first sensor data which may be processed by processing circuitry 116 for storage on memory 124. As described herein, operation 516 may include controlling the one or more propulsion devices 104 to maintain the first AUV 104a at the underwater position as the vessel 108 performs a series of maneuvers around the first AUV 104a as the first sensor data is collected.

Operation 520 includes storing the collected first sensor data in an onboard memory 124 of the first AUV 104a.

Operation 524 includes transmitting the stored first sensor data to a post-mission processor 112. As described herein, the first signature may correspond to an acoustic signature, a magnetic signature, an electronic signature, a pressure signature, and/or a seismic signature of the vessel 108. In some examples, operation 524 occurs over a wired connection upon recovery of the first AUV 104a to the deck of the vessel 108. In other examples, operation 524 occurs over a wireless connection (e.g., Wi-Fi) while the AUV 104a is still in the water or on deck of the vessel 108. In any event, the post-mission processor 112 may then determine the first signature of the vessel 108 using the received first sensor data. The post-mission processor 112 may determine signatures of the vessel 108 in accordance with suitable techniques for doing so.

Operation 512 assumes that the vessel 108 performs a series of maneuvers (e.g., as in FIGS. 3 and 4) while the first AUV 104a remains stationary. However, additionally or alternatively, operation 516 includes controlling the one or more propulsion devices to move the first AUV 104a to other underwater positions around the vessel 108 to collect the additional sensor data at the other underwater positions while the vessel 108 remains stationary. In this case, certain or all operations of the method 500 are repeated. For example, the method 500 may include determining, for the first AUV 104a, a second underwater position at which the first AUV 104a collects second sensor data used to determine the first signature of the vessel 108, which may occur in the same manner as in operation 504. The method may include controlling the first AUV 104a to move to the second underwater position in the same manner as operation 508, confirming that the first AUV 104a is at the second underwater position in the same manner as operation 512, collecting the second sensor data while the first AUV 104a is at the second underwater position in the same manner as in operation 516, and storing the second sensor data in the onboard memory 124 in the same manner as in operation 520. Thereafter, all sensor data collected by the first AUV 104a at the various underwater positions may be transmitted to the post-mission processor 112 in accordance with operation 524.

As may be appreciated, the above discussion of method 500 relates to a single AUV 104 that is used to collect sensor data for characterizing the vessel 108. Accordingly, FIG. 5 may be applied to implementation 300 in FIG. 3. FIG. 6 illustrates a method 600 that may be performed in addition to the method 500 for implementation 400 which involves using multiple AUVs 104 for vessel characterization. For the sake of explanation, the description of the method 600 is performed for a second AUV 104b, but the method 600 may also be applied to AUVs 104c and 104d. Having multiple AUVs 104 may prove useful for obtaining multiple signatures of the vessel 108 without requiring additional vessel or AUV maneuvering.

Operation 604 includes determining, for a second AUV 104b, a second underwater position at which the second AUV 104b collects second sensor data used to determine a second signature of the vessel. In some cases, the second signature is different than the first signature. Here, it should be appreciated that each AUV 104 deployed for vessel characterization may sense different parameters for different signatures of the vessel 108. For example, the AUV 104a may be used to obtain a magnetic signature of the vessel 108 while the second AUV 104b may be used to obtain an acoustic signature of the vessel 108. More signatures may be obtained by additional AUVs (e.g., AUV 104c obtains measurements useful for determining an electronic signature of the vessel 108, and AUV 104d obtains measurements useful for determining a pressure signature of the vessel 108). The second underwater position may be determined in the same manner as that described above for the first underwater position 504.

Operation 608 includes controlling the second AUV 104b to move to the second underwater position. Operation 608 may be performed for the second AUV 104b in the same or similar manner as described above for the first AUV 104a in operation 508. Thereafter, operation 612 may be carried out in the same manner as operation 512 to confirm and/or adjust the positioning of the second AUV 104b to be at the second underwater position. Operation 616 includes collecting the second sensor data while the second AUV 104b is at the second underwater position. Operation 616 may occur in the same or similar manner as operation 516 described above. Operation 620 includes storing the second sensor data in an onboard memory 124 of the second AUV 104b while operation 624 includes transmitting the stored second sensor data to a post-mission processor 112. Thereafter, the post-mission processor 112 may determine the second signature of the vessel 108. As may be appreciated, operations 620 and 624 are performed in the same or similar manner as operations 520 and 524.

The method 600 has been described as a means to gather data for determining a different vessel signature than the method 500 by using different AUVs. However, the method 600 may be performed for the AUV 104b to gather data relevant to determining the same signature as the data being gathered by one or more other AUVs (e.g., 104a, 104c, or 104d). In this case, the post-mission processor 112 may determine that sensor data from one AUV 104 is more reliable than sensor data from another AUV 104, and then determine the relevant vessel signature using the more reliable sensor data. In other examples, the post-mission processor 112 applies one or more algorithms (e.g., an averaging algorithm, a smoothing algorithm, etc.) to multiple sensor datasets so that the sensor data collected by each AUV 104 is taken into account when determining a corresponding vessel signature. In some cases, the post-mission processor 112 compares the sensor data from one AUV 104 to sensor data from one or more other AUVs 104. If there are significant differences, then the post-mission processor 112 may flag both sensor datasets as being potentially unreliable and generate a corresponding alert for an operator, thereby enabling the operator to determine whether to scrap the mismatched sensor data and perform another round of vessel characterization and/or to perform AUV maintenance. If the two sensor datasets are similar enough, then the post-mission processor 112 may determine the data to be reliable and proceed to determine a corresponding vessel signature with one or both of the sensor datasets.

As may be appreciated, one or more of the operations in the methods 500 and 600 are performed autonomously and are carried out without corresponding human input (other than the human input to program the AUV to perform the autonomous operations). For example, operations 504, 508, 512, 516, 520, 604, 608, 612, 616, and 620 may be carried out by one or more AUVs autonomously. However, more or fewer operations may be performed autonomously.

It should be understood that various aspects disclosed herein may be combined in different combinations than the combinations specifically presented in the description and accompanying drawings. It should also be understood that, depending on the example or embodiment, certain acts or events of any of the processes or methods described herein may be performed in a different sequence, and/or may be added, merged, or left out altogether (e.g., all described acts or events may not be necessary to carry out the disclosed techniques according to different embodiments of the present disclosure). In addition, while certain aspects of this disclosure are described as being performed by a single module or unit for purposes of clarity, it should be understood that the techniques of this disclosure may be performed by a combination of units or modules associated with, for example, a computing device.

It should be appreciated that inventive concepts cover any embodiment in combination with any one or more other embodiments, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

Specific details were given in the description to provide a thorough understanding of example embodiments. However, it will be understood by one of ordinary skill in the art that example embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

It should be understood that the terms “first,” “second,” “third,” etc. are used for convenience of description and do not limit example embodiments. For example, a particular element may be referred to a “first” element in some cases, and a “second” element in other cases without limiting example embodiments.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Aspects of the present disclosure may take the form of an embodiment that is entirely hardware, an embodiment that is entirely software (including firmware, resident software, micro-code, etc.) or an embodiment combining software and hardware aspects that may all generally be referred to herein as a “circuit,” “module,” or “system.” Any combination of one or more computer-readable medium(s) may be utilized. The computer-readable medium may be a computer-readable signal medium or a computer-readable storage medium.

A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain or store a program for use by or in connection with an instruction execution system, apparatus, or device.

The terms “determine,” “calculate,” “compute,” and variations thereof, as used herein, are used interchangeably and include any type of methodology, process, mathematical operation or technique.

Example embodiments may be configured as follows:

(1) An autonomous underwater vehicle (AUV), comprising:
one or more propulsion devices that propel the AUV;
one or more sensors that generate sensor data indicative of a signature of a vessel; memory; and
processing circuitry that:
   determines an underwater position at which the AUV collects the sensor data;
   controls the one or more propulsion devices to move the AUV to the underwater position;
   receives the sensor data from the one or more sensors while the AUV is at the underwater position; and
   stores the sensor data in the memory.

(2) The AUV of (1), wherein the signature comprises an acoustic signature of the vessel.

(3) The AUV of one or more of (1) to (2), wherein the signature comprises a magnetic signature of the vessel.

(4) The AUV of one or more of (1) to (3), wherein the signature comprises an electronic signature of the vessel.

(5) The AUV of one or more of (1) to (4), further comprising:
a first positioning system that determines a first surface position of the AUV relative to the vessel, wherein the processing circuitry determines a second surface position of the AUV relative to the vessel or the first surface position, and controls the one or more propulsion devices to move the AUV from the first surface position to the second surface position.

(6) The AUV of one or more of (1) to (5), wherein the processing circuitry controls the one or more propulsion devices to move the AUV from the second surface position to the underwater position.

(7) The AUV of one or more of (1) to (6), further comprising:
a second positioning system that generates underwater position information for the AUV, wherein the processing circuitry confirms that the AUV is at the underwater position based on the underwater position information.

(8) The AUV of one or more of (1) to (7), wherein the first positioning system comprises a satellite navigation system, and wherein the second positioning system comprises an acoustic system.

(9) The AUV of one or more of (1) to (8), wherein the underwater position information comprises underwater position information from one or more other AUVs deployed for obtaining the signature of the vessel or from the vessel.

(10) The AUV of one or more of (1) to (9), wherein the processing circuitry controls the one or more propulsion devices to maintain the AUV at the underwater position as the vessel performs a series of maneuvers around the AUV.

(11) The AUV of one or more of (1) to (10), wherein the processing circuitry determines the underwater position based on the series of maneuvers.

(12) The AUV of one or more of (1) to (11), wherein the processing circuitry:
controls the one or more propulsion devices to move the AUV to other underwater positions around the vessel as the vessel remains stationary; and
receives additional sensor data from the one or more sensors at each other underwater position.

(13) A method, comprising:
determining, for a first autonomous underwater vehicle (AUV), a first underwater position at which the first AUV collects first sensor data used to determine a first signature of a vessel;
controlling the first AUV to move to the first underwater position;
collecting the first sensor data while the first AUV is at the first underwater position; and
storing the collected first sensor data in an onboard memory of the first AUV.

(14) The method of (13), further comprising:
transmitting the stored first sensor data to a post-mission processor that determines the first signature of the vessel.

(15) The method of one or more of (13) to (14) wherein controlling the first AUV to move to the first underwater position comprises:
determining a first surface position of the first AUV relative to the vessel;
controlling the first AUV to move from the first surface position to a second surface position relative to the vessel; and
controlling the first AUV to submerge at the second surface position and move to the first underwater position.

(16) The method of one or more of (13) to (15), further comprising:
controlling the first AUV to maintain the first underwater position while the vessel performs a series of maneuvers, wherein the first underwater position is determined based on the series of maneuvers.

(17) The method of one or more of (13) to (16), further comprising:
determining, for the first AUV, a second underwater position at which the first AUV collects second sensor data used to determine the first signature of the vessel;
controlling the first AUV to move to the second underwater position;
collecting the second sensor data while the first AUV is at the second underwater position; and
storing the second sensor data in the onboard memory.

(18) The method of one or more of (13) to (17), further comprising:
determining, for a second AUV, a second underwater position at which the second AUV collects second sensor data used to determine a second signature of the vessel, the second signature being different than the first signature;
controlling the second AUV to move to the second underwater position; and
collecting the second sensor data while the second AUV is at the second underwater position; and
storing the second sensor data in an onboard memory of the second AUV.

(19) The method of one or more of (13) to (18), wherein the first signature corresponds to a magnetic signature of the vessel, and wherein the second signature corresponds to an acoustic signature of the vessel.

(20) A system, comprising:
a first group of autonomous underwater vehicles (AUVs) that collect first data indicative of a first signature of a vessel;
a second group of AUVs that collect second data indicative of a second signature of the vessel, the second signature being different than the first signature; and
a post-mission processor that:
   determines the first signature based on the first data; and
   determines the second signature based on the second data.

What is claimed is:

1. An autonomous underwater vehicle (AUV), comprising:
one or more propulsion devices that propel the AUV;
one or more sensors that generate sensor data indicative of a signature of a vessel;
memory; and
processing circuitry that:
determines an underwater position at which the AUV collects the sensor data;
controls the one or more propulsion devices to move the AUV to the underwater position;
receives the sensor data from the one or more sensors while the AUV is at the underwater position; and
stores the sensor data in the memory.

2. The AUV of claim 1, wherein the signature comprises an acoustic signature of the vessel.

3. The AUV of claim 1, wherein the signature comprises a magnetic signature of the vessel.

4. The AUV of claim 1, wherein the signature comprises an electronic signature of the vessel.

5. The AUV of claim 1, further comprising:
a first positioning system that determines a first surface position of the AUV relative to the vessel, wherein the processing circuitry determines a second surface position of the AUV relative to the vessel or the first surface position, and controls the one or more propulsion devices to move the AUV from the first surface position to the second surface position.

6. The AUV of claim 5, wherein the processing circuitry controls the one or more propulsion devices to move the AUV from the second surface position to the underwater position.

7. The AUV of claim 6, further comprising:
a second positioning system that generates underwater position information for the AUV, wherein the processing circuitry confirms that the AUV is at the underwater position based on the underwater position information.

8. The AUV of claim 7, wherein the first positioning system comprises a satellite navigation system, and wherein the second positioning system comprises an acoustic system.

9. The AUV of claim 7, wherein the underwater position information comprises underwater position information from one or more other AUVs deployed for obtaining the signature of the vessel or from the vessel.

10. The AUV of claim 1, wherein the processing circuitry controls the one or more propulsion devices to maintain the AUV at the underwater position as the vessel performs a series of maneuvers around the AUV.

11. The AUV of claim 10, wherein the processing circuitry determines the underwater position based on the series of maneuvers.

12. The AUV of claim 1, wherein the processing circuitry:
controls the one or more propulsion devices to move the AUV to other underwater positions around the vessel as the vessel remains stationary; and
receives additional sensor data from the one or more sensors at each other underwater position.

13. A method, comprising:
determining, for a first autonomous underwater vehicle (AUV), a first underwater position at which the first AUV collects first sensor data used to determine a first signature of a vessel;
controlling the first AUV to move to the first underwater position;
collecting the first sensor data while the first AUV is at the first underwater position; and
storing the collected first sensor data in an onboard memory of the first AUV.

14. The method of claim 13, further comprising:
transmitting the stored first sensor data to a post-mission processor that determines the first signature of the vessel.

15. The method of claim 13, wherein controlling the first AUV to move to the first underwater position comprises:
determining a first surface position of the first AUV relative to the vessel;
controlling the first AUV to move from the first surface position to a second surface position relative to the vessel; and
controlling the first AUV to submerge at the second surface position and move to the first underwater position.

16. The method of claim 13, further comprising:
controlling the first AUV to maintain the first underwater position while the vessel performs a series of maneuvers, wherein the first underwater position is determined based on the series of maneuvers.

17. The method of claim 13, further comprising:
determining, for the first AUV, a second underwater position at which the first AUV collects second sensor data used to determine the first signature of the vessel;
controlling the first AUV to move to the second underwater position;
collecting the second sensor data while the first AUV is at the second underwater position; and
storing the second sensor data in the onboard memory.

18. The method of claim 13, further comprising:
determining, for a second AUV, a second underwater position at which the second AUV collects second sensor data used to determine a second signature of the vessel, the second signature being different than the first signature;
controlling the second AUV to move to the second underwater position; and
collecting the second sensor data while the second AUV is at the second underwater position; and
storing the second sensor data in an onboard memory of the second AUV.

19. The method of claim 18, wherein the first signature corresponds to a magnetic signature of the vessel, and wherein the second signature corresponds to an acoustic signature of the vessel.

20. A system, comprising:
a first group of autonomous underwater vehicles (AUVs) that collect first data indicative of a first signature of a vessel;
a second group of AUVs that collect second data indicative of a second signature of the vessel, the second signature being different than the first signature; and
a post-mission processor that:
determines the first signature based on the first data; and
determines the second signature based on the second data.
